(19) United States
(12) Patent Application Publication
(10) Pub. No.: US 2006/0190793 A1
(43) Pub. Date: Aug. 24, 2006

(54) Establishing a reference bit in a bit pattern

(76) Inventor: Marlin Viss, Santa Rosa, CA (US)

Correspondence Address: AGILENT TECHNOLOGIES, INC.;Legal Department, DL 429, Intellectual Property Administration, P.O. Box 7599, Loveland, CO, 80537-0599, US

(21) Appl. No.: 11/060,860

(22) Filed: Feb. 18, 2005

(51) Int. Cl. G01R 31/28; G06F 11/00

(52) U.S. Cl. 714/738

(57) ABSTRACT

A method establishes a reference bit in a bit pattern. The method includes (a) identifying a series of bit sequences in the bit pattern including all bit sequences having the largest number of consecutive bits with a common logic state and (b) assigning a reference bit based on one bit sequence in the series when the series includes only one bit sequence. The method includes (c) identifying a series of bit sequences in the bit pattern that includes all bit sequences that have the largest number of consecutive bits with an alternative logic state from a last prior identified series of bit sequences, and that are adjacent to each bit sequence in the last prior identified series of bit sequences. The method assigns a reference bit based on one bit sequence in the series identified in (c) when the series identified in (c) includes only one bit sequence.

### BACKGROUND OF THE INVENTION

Characterizing a digital communication system typically involves stimulating the system with test signals and then measuring the response of the system to the test signals.

One type of test signal includes a repetitive bit pattern having long strings with relatively few logic zero bits or logic one bits. This type of bit pattern tends to cause baseline wander in a digital communication system and is useful for testing the performance of AC-coupled portions of the digital communication system. Other types of test signals have bit patterns that have a low number of transitions between logic zero bits and logic one bits. These test signals are useful for testing the performance of clock recovery circuits within digital communication systems. Another type of test signal includes a pseudo-random bit sequence (PRBS). The PRBS can be readily generated with a pattern generator to provide a repetitive bit pattern that has statistical attributes of random data present in some types of data signals. Stimulation of the digital communication system with the PRBS can simulate the performance of the digital communication system under realistic operating conditions.

While these examples of test signals are well known in the art, designers of digital communication systems often define custom test signals that have different types of repetitive bit patterns. The responses of the digital communication systems to the test signals can be measured using an equivalent-time oscilloscope or other type of measurement instrument. However, a typical measurement instrument provides no convenient means for establishing a reference position within a repetitive bit pattern of a test signal. Establishing a reference position within a bit pattern, indicated by a reference bit, enables pattern-dependent attributes of the digital communication system to be observed on different measurement systems, or to be observed when the test signals are provided to different devices under test (DUTs) or to different points in the digital communication systems, or when the test signals is applied to different configurations of DUTs.

### BRIEF DESCRIPTION OF THE DRAWINGS

FIG. 1 shows one example of a measurement configuration suitable for implementing a method for establishing a reference bit within a bit pattern, according to embodiments of the present invention.

FIG. 2A shows one example of a signal that includes a bit pattern that is repetitive.

FIG. 2B shows a bit sequence that corresponds to the bit pattern shown in FIG. 2A.

FIG. 3 shows one example of a flow diagram of the method for establishing a reference bit within a bit pattern, according to embodiments of the present invention.

### DETAILED DESCRIPTION OF THE EMBODIMENTS

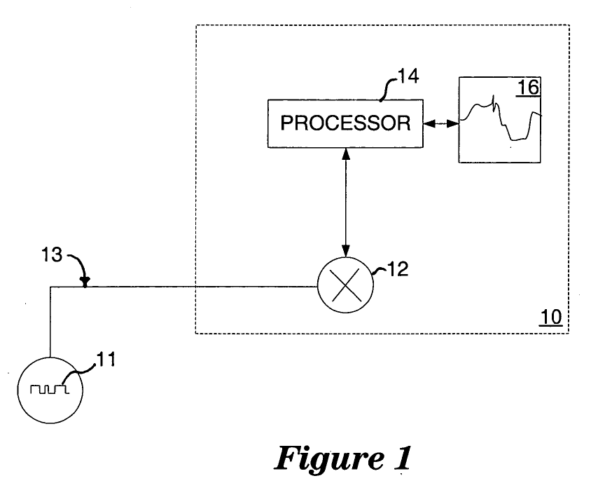

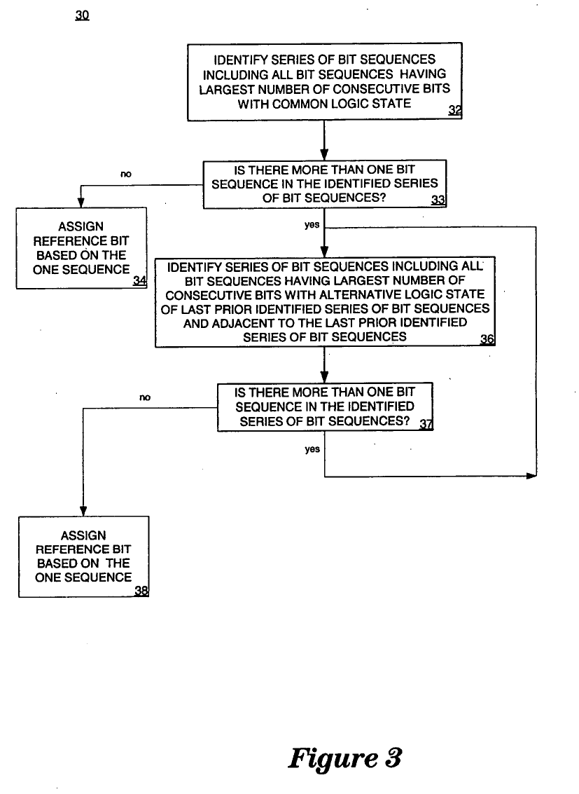

FIG. 1 shows one example of a measurement configuration suitable for implementing a method 30 for establishing a reference bit R within a bit pattern 11, according to the embodiments of the present invention. The measurement configuration includes a digital communications analyzer, such as an AGILENT TECHNOLOGIES, INC. model 86100C DIGITAL COMMUNICATIONS ANALYZER, or other type of signal analyzer 10. The signal analyzer 10 in this example includes a sampler 12, and a processor 14 in signal communication with the sampler 12 and a display 16. The sampler 12 acquires samples of a signal 13 that is applied to the signal analyzer 10. The processor 14 typically includes software suitable for processing the acquired samples of the signal 13 according to the method 30 (shown in FIG. 3).

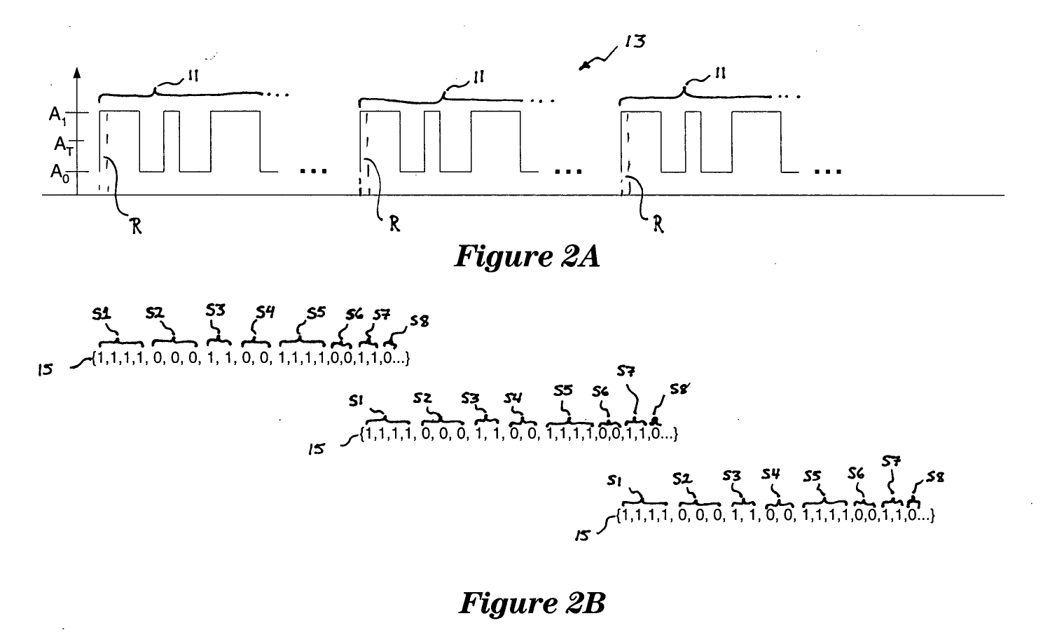

FIG. 2A shows one example of the signal 13 represented by a waveform of amplitude versus time. In this example, the signal 13 is a digital signal having a bit pattern (hereinafter “bit pattern 11”) that is repetitive. The bits within the bit pattern 11 are shown having two alternative logic states. A logic one state (indicated as ‘logic 1”) is represented in the signal 13 by an amplitude level A₁ and a logic zero state (indicated as “logic 0”) is represented in the signal 13 by an amplitude level A₀. Four repetitions of the bit pattern 11 are shown in the waveform of the signal 13 in FIG. 2A. The bits within each repetition of the bit pattern 11 are represented by the amplitude levels A₁, A₀. The remainder of the bits in each repetition of the bit pattern 11, although represented by these amplitude levels A₁, A₀, is indicated by an ellipsis.

The bit pattern 11 has a corresponding bit string 15, shown in FIG. 2B, which indicates the logic states that are represented in the bit pattern 11. For example, the portions of each of the bit patterns 11 shown in the waveform of FIG. 2A are at the amplitude level A₁ for a duration of four bits. This is represented in FIG. 2B by a bit sequence S1 having four consecutive 1s. The bit pattern is then followed by adjacent bits at the amplitude level A₀ for a duration of three bits and is represented in FIG. 2B by the bit sequence S2 having three consecutive 0s. The bit pattern 11 is then followed by adjacent bits at the amplitude level A₁ for a duration of two bits, indicated in FIG. 2B by the bit sequence S3 having two consecutive 1s. The bit pattern 11 is then followed by adjacent bits at the amplitude level A₀ for a duration of two bits and represented in FIG. 2B by the bit sequence S4 having two consecutive 0s. The bit pattern 11 is then followed by adjacent bits at the amplitude level A₁ for a duration of four bits that are represented in FIG. 2B by the bit sequence S5 having four consecutive 1s. The bit pattern 11 is then followed by adjacent bits at the amplitude level A₀ for a duration of two bits, represented in FIG. 2B by the bit sequence S6 having two consecutive 0s. The bit pattern 11 is then followed by the amplitude level A₁ for a duration of two bits, represented in FIG. 2B by the bit sequence S7 having two consecutive 1s. The bit pattern 11 is then followed by the amplitude level A₀ for a duration of one bit and is represented in FIG. 2B by the bit sequence S8, and so on.

The corresponding bit string 15 for a given bit pattern 11 can be established by comparing the amplitude of each bit in the bit pattern to an amplitude threshold A_{T} and then sorting each of the bits into a corresponding logic state based on the comparison. Each bit in the bit pattern 11 that has an amplitude greater than the amplitude threshold A_{T} is designated as a “1” in the bit string 15, whereas each bit in the bit pattern 11 that has an amplitude less than the amplitude threshold A_{T} is designated as a “0” in the bit string 15.

FIG. 3 shows one example of a flow diagram of the method 30, for establishing a reference bit R within a bit pattern 11, according to embodiments of the present invention. Step 32 of the method 30 includes identifying a series of bit sequences in each repetition of the bit pattern 11. The identified series of bit sequences includes all sequences of bits that have the largest number of consecutive bits with a common logic state, for example the largest numbers of consecutive logic 1s or logic 0s. To identify the series of bit sequences, step 32 typically includes establishing the corresponding bit string 15 for the bit pattern 11 and then searching through the bit string 15 to find the largest number of consecutive 1s or 0s. All bit sequences within the bit string 15 that have the largest number of consecutive 1s (or 0s) are then included in the series of bit sequences. For the portion of the bit pattern 11 of the signal 13 shown in FIG. 2A and the corresponding bit string 15 shown in FIG. 2B, the largest number of consecutive bits with a common logic state is four, since there are four consecutive 1s, but only three consecutive 0s.

Step 33 of the method 30 includes determining whether the series of bit sequences identified in step 32 includes one bit sequence, or more than one bit sequence. This step typically includes counting the number of bit sequences that have the largest number of consecutive bits. When the identified series of bit sequences includes only one bit sequence, for example, when there is only one bit sequence that has the largest number of consecutive 1s (or 0s), the method 30 then assigns the reference bit R based on the one sequence in the identified series (step 34). The reference bit R assigned in step 34 can be a designated bit within the one bit sequence in the series as shown in FIG. 2A. Alternatively, the reference bit R assigned in step 34 is a designated bit that is a specified number of bits offset from the one bit sequence in the series. Once the reference bit R is assigned in step 34, the reference bit R can then be located in one or more subsequent repetitions of the bit pattern 11 by searching through the corresponding bit string 15 for the largest number of consecutive 1s (or 0's). For example, locating the reference bit R may involve searching for the four consecutive 1's in the bit string. When the number of bits in the bit pattern 11 is known, the reference bit can be located in successive repetitions of the bit pattern 11 by counting, from the assigned reference bit R, the number of bits equal to one or more integer multiples of the bit length of the bit pattern 11. The reference bit R is then located in the bit pattern 11 based on the counted number of bits. The assigned reference bit R can also be located by delaying the trigger of the signal analyzer 10 by a time duration equivalent to that of one or more integer multiples of the time duration of the bit pattern 11.

When the identified series of bit sequences includes more than one bit sequence, for example, when there is more than one bit sequence that has the largest number of consecutive 1's, the method 30 then includes identifying another series of bit sequences in the bit pattern 11 (step 36). The series of bit sequences identified in step 36 includes all bit sequences that are adjacent to each of the bit sequences in the last prior identified series of bit sequences, and that have the largest number of consecutive bits with an alternative logic state from a last prior identified series of bits. For example, when the last prior identified series of bit sequences, resulting from step 32 for example, has the logic one state, the alternative logic state is the logic zero state. When the last prior identified series of bit sequences has the logic zero state, the alternative logic state is the logic one state. For the example bit pattern shown in FIG. 2A and the corresponding bit string shown in FIG. 2B, step 34 includes searching the bit string to determine the largest number of consecutive 0's that are adjacent to each bit sequence in the series of bit sequences identified in step 32 as having the largest number of consecutive is.

Step 37 of the method 30 includes determining whether the series of bit sequences identified in step 36 includes one bit sequence, or more than one bit sequence. When this series of bit sequences includes only one bit sequence, for example, when there is only one bit sequence that has the largest number of consecutive 0s that are adjacent to the consecutive 1s in the last prior identified series of bit sequences, the method 30 assigns the reference bit R based on the one bit sequence in the identified series of bits (step 36). The reference bit R assigned in step 38 can be a designated bit within the one bit sequence in the series. Alternatively, the reference bit R assigned in step 38 is a designated bit that is a specified number of bits offset from the one bit sequence in the series. Once the reference bit is assigned in step 38, the reference bit R can then be located in one or more subsequent repetitions of the bit pattern 11 by repeating steps 32-38 of the method 30. When the number of bits in the bit pattern is known, the reference bit can be located in successive repetitions of the bit pattern 11 by counting, from the assigned reference bit R, the number of bits equal to one or more integer multiples of the bit length of the bit pattern 11. The assigned reference bit R can also be located by delaying the trigger of the signal analyzer 10 by a time duration equivalent to that of one or more integer multiples of the time duration of the bit pattern 11.

When the series of bit sequences identified in step 36 includes more than one bit sequence, for example, when there is more than one bit sequence that has the largest number of consecutive 0's, the method 30 then repeats steps 36-38 until step 37 determines that here is only one bit sequence in the identified series of bit sequences in step 36 and the reference bit R is assigned in step 38.

An embodiment of the method 30 is illustrated by an example. In this example, the portion of the bit pattern 11 of the signal 13 shown in FIG. 2A and the portion of the corresponding bit string 15 shown in FIG. 2B include the bit sequences with the largest number of consecutive bits having a common logic state. Step 32 of the method 30 identifies a series of bit sequences that includes the bit sequences S1, S5, since each of these bit sequences has the four consecutive 1s. The largest number of consecutive 0s is three, occurring in bit sequence S2. Step 33 of the method 30 then establishes that there is more than one bit sequence in the series of bit sequences, since there are two bit sequences that have the largest number of consecutive bits, i.e. four consecutive 1s. Therefore, step 34 does not assign the reference bit R. Step 36 identifies a series of bit sequences that are adjacent to the bit sequences S1, S5 and that include all bit sequences having the largest number of consecutive 0s. In this example, the series of bit sequences includes the bit sequence S2, which has three consecutive 0s. In this example, there are no other bit sequences having three consecutive 0s. According to step 37, the method 30 establishes that there is only one bit sequence in the series of bit sequences and the reference bit R is assigned according to step 38.

While the embodiments of the present invention have been illustrated in detail, it should be apparent that modifications and adaptations to these embodiments may occur to one skilled in the art without departing from the scope of the present invention as set forth in the following claims.

1. A method for establishing a reference bit in a bit pattern, comprising:
(a) identifying a series of bit sequences in the bit pattern that includes all bit sequences that have the largest number of consecutive bits having a common logic state; and
(b) assigning a reference bit based on one bit sequence in the series of bit sequences when the series of bit sequences includes not more than one bit sequence.

2. The method of claim 1 further comprising (c) identifying a series of bit sequences in the bit pattern that includes all bit sequences in the bit pattern that have the largest number of consecutive bits with an alternative logic state from a last prior identified series of bit sequences, and that are adjacent to each bit sequence in the last prior identified series of bit sequences.

3. The method of claim 2 further comprising (d) assigning a reference bit based on one bit sequence in the series of bit sequences identified in (c) when the series of bit sequences identified in (c) includes not more than one bit sequence.

4. The method of claim 3 further comprising repeating (c) and (d) until the series of bit sequences identified in (c) includes not more than one sequence of bits.

5. A method for establishing a reference bit in a bit pattern, comprising:
(a) identifying a series of bit sequences in the bit pattern that includes all bit sequences that have the largest number of consecutive logic one bits; and
(b) assigning a reference bit based on one bit sequence in the series of bit sequences when there is not more than one bit sequence having the largest number of consecutive logic one bits.

6. The method of claim 5 further comprising (c) identifying a series of bit sequences in the bit pattern that includes all bit sequences in the bit pattern that have the largest number of consecutive bits with an alternative logic state from a last prior identified series of bit sequences, and that are adjacent to each bit sequence in the last prior identified series of bit sequences.

7. The method of claim 6 further comprising (d) assigning a reference bit based on one bit sequence in the series of bit sequences identified in (c) when the series of bit sequences identified in (c) includes not more than one bit sequence.

8. The method of claim 7 further comprising repeating (c) and (d) until the series of bit sequences identified in (c) includes not more than one sequence of bits.

9. A method for establishing a reference bit in a bit pattern, comprising:
(a) identifying a series of bit sequences in the bit pattern that includes all bit sequences that have the largest number of consecutive logic one bits; and
(b) assigning a reference bit based on one bit sequence in the series of bit sequences when there is not more than one bit sequence having the largest number of consecutive logic zero bits.

10. The method of claim 9 further comprising (c) identifying a series of bit sequences in the bit pattern that includes all bit sequences in the bit pattern that have the largest number of consecutive bits with an alternative logic state from a last prior identified series of bit sequences, and that are adjacent to each bit sequence in the last prior identified series of bit sequences.

11. The method of claim 10 further comprising (d) assigning a reference bit based on one bit sequence in the series of bit sequences identified in (c) when the series of bit sequences identified in (c) includes not more than one bit sequence.

12. The method of claim 11 further comprising repeating (c) and (d) until the series of bit sequences identified in (c) includes not more than one sequence of bits.
